(19) United States
(12) Patent Application Publication
(10) Pub. No.: US 2025/0346484 A1
(43) Pub. Date: Nov. 13, 2025

(54) MICROMECHANICAL DEVICE AND METHOD FOR PRODUCING A MICROMECHANICAL DEVICE HAVING A MEMS SUBSTRATE AND A CAP SUBSTRATE AND A CAVERN ENCLOSED BY MEMS SUBSTRATE AND CAP SUBSTRATE

(71) Applicant: Robert Bosch GmbH, Stuttgart (DE)

(72) Inventor: Raphael Schuler, Tuebingen (DE)

(21) Appl. No.: 19/185,624

(22) Filed: Apr. 22, 2025

(30) Foreign Application Priority Data
May 13, 2024 (DE) 10 2024 204 403.2

(51) Int. Cl. B81C 1/00; B81B 7/00

(52) U.S. Cl. CPC B81C 1/00293; B81B 7/0041; B81B 2203/0315; B81B 2203/033; B81B 2207/012; B81C 2201/0132; B81C 2201/0156; B81C 2201/0174; B81C 2203/0109; B81C 2203/0172; B81C 2203/036

(57) ABSTRACT

A micromechanical device and a method for producing a micromechanical device. The micromechanical device includes a MEMS substrate, a functional layer, and a cap part. The functional layer is located between the MEMS substrate and the cap part. The cap part includes a cap substrate. The micromechanical device has a main extension plane. The micromechanical system and the cap part enclose a cavern. The micromechanical device has a sealed cavern access.

### CROSS REFERENCE

The present application claims the benefit under 35 U.S.C. § 119 of German Patent Application No. DE 10 2024 204 403.2 filed on May 13, 2024, which is expressly incorporated herein by reference in its entirety.

### FIELD

The present invention relates to a micromechanical device having a MEMS substrate and a cap substrate and a method for producing a micromechanical device. Many such micromechanical devices and methods for producing micromechanical devices having a sensor substrate and a plurality of sensor cores located thereon, in particular microelectromechanical (MEMS) rotation rate sensor cores and acceleration sensor cores, and cap substrates applied thereto are conventional.

Such MEMS-based sensors generally place different requirements on the internal cavern pressure under which they are used and, as a result of the miniaturization of components, more and more monolithically integrated sensors, i.e., sensors implemented on the same chip, with different requirements on the internal cavern pressure are needed.

Sensor cores of microelectromechanical (MEMS) rotation rate sensors and acceleration sensors are conventionally arranged between the MEMS substrate and an applied cap substrate in caverns that each have or require differently set internal cavern pressures.

One conventional method for setting different internal pressures in the caverns of MEMS-based sensors on a combined MEMS component is the laser reseal method. Various variants of the laser reseal method are described in Germany Patent Application Nos. DE 10 2014 202 801 A1, DE 10 2017 215 531 A1, DE 10 2017 207 111 A1, and DE 10 2020 214 831 A1. The basic principle of the laser reseal method is to open the already sealed (in particular by capping) caverns of selected sensor cores in a combined MEMS component subsequently or to keep the caverns of selected sensor cores open during the bonding process (the capping), to set a desired ambient pressure, and to reseal these caverns hermetically by melting shut a cavern access opening by means of laser irradiation.

These conventional methods require prestructuring or recessing of at least a subregion of the cap substrate both in the case of a cavern access formed in the cap substrate and in the case of a cavern access formed in the MEMS substrate, so that this region is generally not available for electronic circuits, as, for example, in the ASICs-containing cap substrates of ASICap technology.

The necessary prestructuring and/or recessing of this subregion for the conventional methods leads to further disadvantages in the processing (also in the case of cap substrates that do not have ASIC regions). The oxide height to be opened in the region of the laser fusion seal on the cap wafer leads to high polymer particle loading in the edge region and on the rear side of the wafer. Further processing in the series process is therefore not possible or only possible at significant cleaning expenses. In the case of ASICs-containing cap substrates, structuring of the dielectric layers of the ASIC exposes its flanks, as a result of which hydrogen stored in the layers can escape and change the internal cavern pressure.

### SUMMARY

An object of the present invention is to provide a laser reseal method which, unlike conventional laser reseal method, does not require prestructuring and/or recessing of the cap wafer in the reseal region loaded by laser energy and thus does not have the aforementioned disadvantages.

A micromechanical device according to the present invention having a MEMS substrate, a functional layer, and a cap part has the advantage over the related art that laser radiation that is used to seal caverns in the micromechanical device and misses the edge material to be melted of a cavern opening, is absorbed and/or reflected and/or scattered by protective material that lies between the MEMS substrate and the cap part, rather than impinging on a region of the cap part that is useful for electronic circuits.

Advantageous embodiments and developments of the present invention can be found in the disclosure herein.

According to an advantageous embodiment of the present invention, protective material used to absorb laser radiation is also used as an etch stop, as a result of which trench etching carried out from the outside of the MEMS substrate for the purpose of piercing the blind hole in the MEMS substrate does not penetrate to the cap part carrying electronic circuits and does not cause any damage there.

According to an advantageous embodiment of the present invention, the cavern access is formed substantially in parallel with the main extension plane of the micromechanical device by at least a portion of the micromechanical device, whereby the protection of the cap part from laser radiation is ensured despite the occurrence of beam divergences of the laser radiation and despite a possible penetration and spread of the laser radiation in edge regions of the cavern opening.

According to an advantageous embodiment of the present invention, the cavern access is formed in a Z shape by at least a portion of the micromechanical device, whereby the protection of the cap part from laser radiation is ensured despite the occurrence of beam divergences of the laser radiation and despite a possible penetration and spread of the laser radiation in edge regions of the cavern opening.

A further object of the present invention is a method for producing a micromechanical device having a MEMS substrate, a functional layer, and a cap part.

The method according to the present invention for producing a micromechanical device having a MEMS substrate, a functional layer, and a cap part is advantageous over the related art because laser radiation that enters the cavern access opening of the micromechanical device and misses the edge material to be melted of the cavern access opening, is absorbed and/or reflected and/or scattered by protective material that lies between the MEMS substrate and the cap part, rather than impinging on a region of the cap part that is useful for electronic circuits.

According to an advantageous embodiment of the method according to the present invention, it is provided that an ASIC substrate carrying ASIC circuits is used as a cap part, wherein no special processing on the ASIC side is necessary for the laser reseal or the resealing of the cavern access opening by means of laser radiation.

In an advantageous embodiment of the method according to the present invention, a lithography mask created for structuring the grown silicon layer is created as a material that protects from subsequent trench etching for the purpose of piercing the cavern. In addition, a standoff layer, which is used on the one hand as a spacer to the cap part and on the other hand as an absorbent material that protects from laser radiation, is deposited on the lithography mask, and the lithography mask is thus protected from etching processes.

In an advantageous embodiment of the method according to the present invention, the substructure is removed by a gas phase etching process, which substantially does not attack the spacer standoff layer.

In a further advantageous embodiment of the present invention, the trench etched from the rear side of the MEMS substrate is produced with a diameter of about 150 μm and a depth of about 150 μm to about 400 μm.

In a further advantageous embodiment of the method according to the present invention, the blind hole is only created after a start layer of polycrystalline silicon has been deposited on the substructure and doped, as a result of which relocation of the trench profile by long high-temperature steps is avoided.

According to an advantageous example embodiment of the method according to the present invention, it is provided that the blind hole is produced with a diameter corresponding approximately to the thickness of the grown silicon layer and is etched to a depth of about 50 μm to about 150 μm. According to the present invention, the possibility that trench structures onto which a layer of grown material is applied, such as epi-poly or epitaxially grown polycrystalline material, in particular silicon, which has a thickness (or height) that approximately corresponds to the width of the trench structures can be sealed by the grown material is particularly advantageous.

In an advantageous example embodiment of the method according to the present invention, a material layer absorbing and/or reflecting and/or scattering laser radiation is produced above the sensor core layer.

An advantageous example embodiment of the method according to the present invention provides for tempering before the internal cavern pressure is set and before the cavern access opening is sealed.

In an advantageous example embodiment of the method according to the present invention, the produced layers and etched trenches correspond to dimensionally modified but otherwise standard layers and trenches of standard processes used to produce MEMS.

Exemplary embodiments of the present invention are shown in the figures and explained in more detail in the following description.

### BRIEF DESCRIPTION OF THE DRAWINGS

FIG. 1 shows a schematic illustration of a micromechanical device according to the present invention, which comprises two different sensors, for example a rotation rate sensor and an acceleration sensor, and has an ASIC cap part as well as a MEMS substrate with cavern access, wherein the micromechanical device has been pierced by trench etching from the outside of the MEMS substrate, wherein the ASCI cap part and the MEMS substrate are connected to each other.

FIG. 2 shows a schematic illustration of a region of a recess in a substructure of a micromechanical device according to the present invention and of a cavity-containing partial structure created in the substructure, prior to the trench etching of a blind hole.

FIG. 3 shows a schematic illustration of the region shown in FIG. 2 of the recess in the substructure of the micromechanical device according to the present invention and of the cavity-containing partial structure created in the substructure, after the trench etching of the blind hole.

FIG. 4 shows a schematic illustration of the region around a covered blind hole of a micromechanical device according to the present invention, a grown polycrystalline silicon layer as the sensor core layer, a lithography mask used for subsequently structuring the sensor core layer and kept closed above the blind hole, a spacer standoff layer and a mask for protecting the standoff layer from the subsequent trench etching in the region above the blind hole.

FIG. 5 shows a schematic illustration of the region around a covered blind hole of the micromechanical device according to the present invention, a structured sensor core layer, and a laterally offset trench leading to the substructure of the sensor core layer.

FIG. 6 shows a schematic illustration of the region around a covered blind hole after removal of the substructure of the sensor core layer, and the remaining residues of the lithography mask used for structuring the sensor core layer, wherein the removal has been carried out by a gas phase etching process.

FIG. 7 shows a schematic illustration of the region around a produced cavern access and a section of the ASIC cap part after bonding of the MEMS substrate and the ASIC cap part, which shows a recess produced in the MEMS substrate by trench etching from the rear side of the MEMS substrate.

### DETAILED DESCRIPTION OF EXAMPLE EMBODIMENTS

The same parts in the various figures are always provided with the same reference signs and are therefore usually named or mentioned only once.

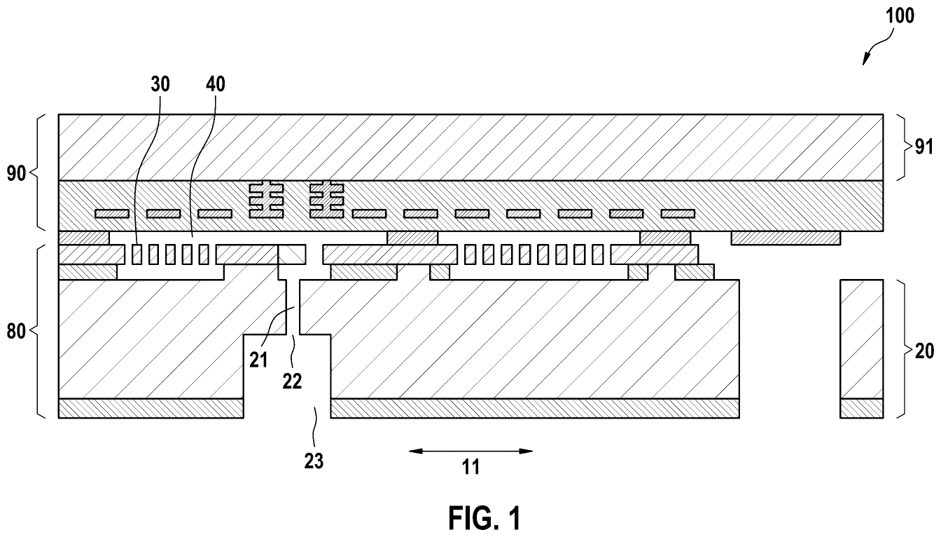

FIG. 1 shows the cross-section of a micromechanical device 100 according to the present invention, wherein the micromechanical device 100 contains a micromechanical system 80 comprising a MEMS substrate 20 and a functional layer 30. The micromechanical device 100 also comprises a cap part 90 connected to the micromechanical system 80. The functional layer 30 is located between the MEMS substrate 20 and the cap part 90, and the cap part 90 comprises a cap substrate 91. The cross-sectional plane is oriented perpendicularly to a main extension plane 11 of the micromechanical device 100 and intersects both a recess 23 in the MEMS substrate 20 and a cavern access 21. By way of example, the micromechanical device 100 comprises a cap part 90 having an ASIC circuit, the ASIC circuit is an ASIC circuit that is produced in a conventional manner and does not require any prestructuring, preprocessing, or recessing of a subregion in the cap part 90 with regard to the laser reseal. In the functional layer 30 located between the cap part 90 and the MEMS substrate 20, there are two sensors or sensor cores (in particular produced by reactive ion etching), for example the sensor cores of a rotation rate sensor and of an acceleration sensor. For implementing the spring-mass system required for the measurement principle, the sensor cores are carried by support structures and are otherwise surrounded by a gas-filled cavern volume, which ensures the necessary degrees of freedom of movement. Only the cavern (shown on the left) to which the cavern access 21 leads is denoted by reference sign 40. The caverns of both sensor cores are spatially and laterally separated from each other, wherein the internal pressure of the cavern (not denoted by reference signs) shown on the right in the figure has been set prior to the bonding process of the MEMS substrate 20 or of the micromechanical system 80 to the cap part 90. The MEMS substrate 20 and the cap part 90 (or the micromechanical system 80 and the cap part 90) are connected in a conventional manner by an (in particular eutectic) bonding process by means of bond pads located on the cap part 90. The cavern access 21 has an access portion extending substantially in parallel with the main extension plane 11, and the rectilinear path through the portion of the cavern access 21 that extends perpendicularly to the main extension plane and is visible from outside the micromechanical device 100 by means of optical and non-destructive aids ends according to the exemplary embodiment shown in FIG. 1 on a view-obstructing material within the functional layer 30.

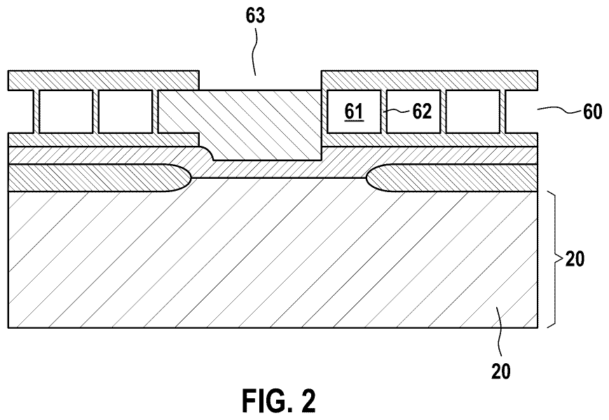

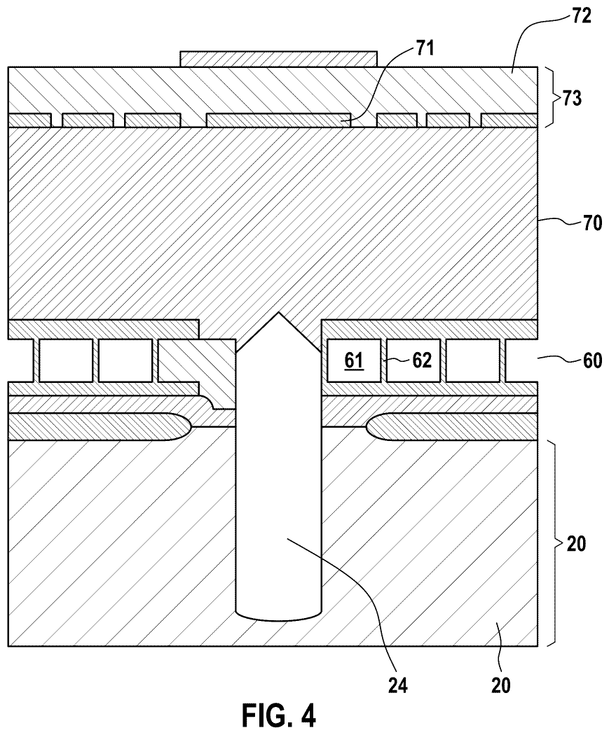

FIG. 2 shows a region of a recess 63 (in a substructure 60) of a micromechanical device 100 according to the present invention in cross-section, wherein the cross-sectional plane is oriented perpendicularly to the main extension plane 11. The state shown is the state after the production of the substructure 60 from oxides and prior to the production of a blind hole 24. The substructure 60 has a partial structure 62 containing a cavity 61 or a plurality of cavities 61. The dimensions of the recess 63 are selected such that a blind hole diameter corresponding approximately to the thickness of the subsequently deposited sensor core layer 70 (cf. FIG. 4) can be produced.

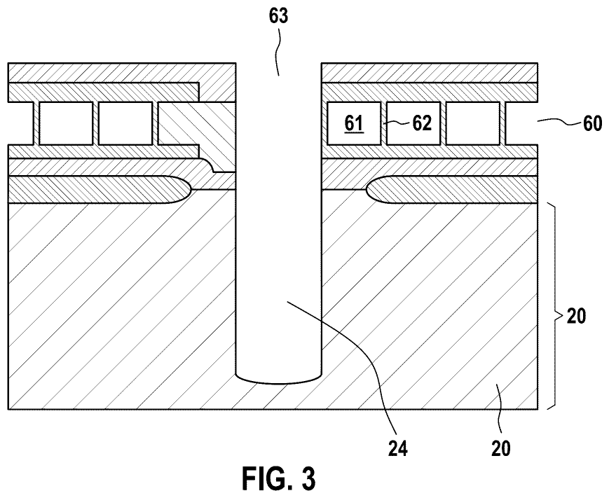

In FIG. 3, a blind hole 24, which later serves as a ventilation access or vent hole, and a substructure 60 of a micromechanical device 100 according to the present invention after the production of the blind hole 24 by trench etching are shown in cross-section, wherein the cross-sectional plane is oriented perpendicularly to the main extension plane 11. A lithography mask for carrying out the trench etching allows the blind hole 24 to be produced with the necessary diameter, wherein the blind hole 24 is preferably etched with the DRIE process or the Bosch process and preferably to a depth of a few hundred micrometers. In order to avoid relocation of the trench profile by long high-temperature steps, such as doping a start poly or an initially applied layer of polycrystalline material, in particular silicon, prior to epi-deposition or epitaxial deposition, vent hole trenching can preferably be carried out only after this start poly deposition or deposition of an initially applied layer of polycrystalline material (in particular silicon) and after doping.

In FIG. 4, the blind hole 24, which later serves as a ventilation access or vent hole, and the surrounding region of a micromechanical device 100 according to the present invention in the state after the deposition of the functional layer 30 (comprising a material layer 70 and a material layer stack 73) are shown in cross-section, wherein the cross-sectional plane is oriented perpendicularly to the main extension plane 11 of the micromechanical device 100. The material layer 70 is a sensor core layer from which the sensor cores or at least their main material is produced. The material layer 70, in particular epitaxially grown polycrystalline silicon or epi-poly, was grown to about 23 μm. According to the present invention, it is in particular advantageous that trench structures can be closed (or sealed) by means of grown material when the thickness of grown material, in particular epi-poly or epitaxially grown polycrystalline material, in particular silicon, is approximately equal to the width of the trench structures. This epi-poly or epitaxially grown polycrystalline material, in particular silicon, is therefore used according to the present invention to reseal the ventilation access or the vent hole. A small topography remains on the surface but is polished out during chemical mechanical planarization or CMP. Typically, approximately 3 μm of epi-poly or epitaxially grown polycrystalline material, in particular silicon, is removed during the chemical mechanical planarization or CMP. The material layer stack 73 has a material layer 71 and a material layer 72. The material layer 71 is a lithography mask for the subsequent etching process used to structure the sensor core layer 70. The material layer 72 is a standoff layer, which is used to ensure a distance between the sensor core layer 70 and the cap part 90. The sensor core layer 70, in particular of polycrystalline silicon, is epitaxially deposited on the substructure 60 and covers the previously produced blind hole 24. The lithography mask 71 used for subsequently structuring the sensor core layer 70 is kept closed in the region above the blind hole 24 so that subsequent trench etching from the rear side of a MEMS substrate 20 cannot penetrate to the cap part 90. The standoff layer 72, which serves to produce spacers between the sensor core and the cap part 90, has been deposited on the sensor core layer 70 and the lithography mask 71. In the region above the blind hole 24, an oxide mask is created, which is kept closed at this point for protection from the subsequent structuring of the sensor core layer 70. The lithography mask 71 used for structuring the sensor core layer 70 is kept open at a point which is laterally offset from the blind hole 24 and is located above a partial structure 62 of the substructure 60 that contains a cavity 61, so that the subsequent trench etching at this point hits the partial structure 62 of the substructure 60 that contains a cavity 61.

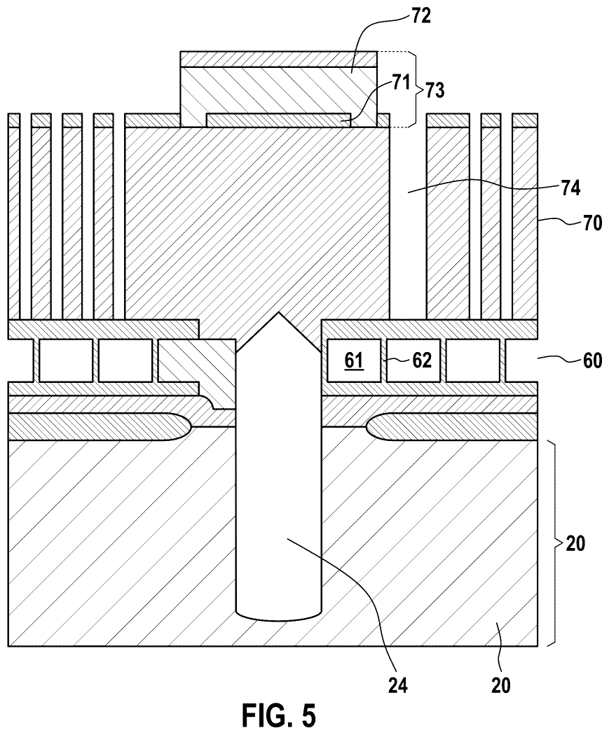

In FIG. 5, the blind hole 24 and the surrounding region of a micromechanical device 100 according to the present invention in the state the trench etching for structuring a sensor core layer 70 are shown in cross-section, wherein the cross-sectional plane is oriented perpendicularly to the main extension plane 11 of the micromechanical device 100. The trench etching has produced a trench 74, whereby access from the space above the sensor core layer 70 to a partial structure 62 of the substructure 60 that contains a cavity 61, preferably a buried cavern, is provided. Above the blind hole 24, a standoff layer 72 has been preserved by the previously applied oxide mask during trench etching and is used in the subsequent gas phase etching process to keep a portion of a lithography mask 71 used for structuring the sensor core layer 70, above the blind hole 24 from being removed by HF gas.

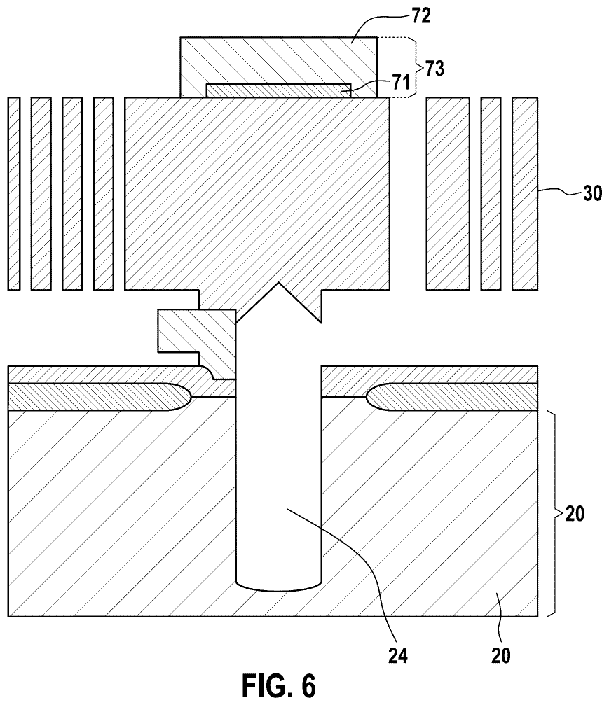

In FIG. 6, the blind hole 24 and the surrounding region of a micromechanical device 100 according to the present invention in the state the gas phase etching process by means of HF gas are shown in cross-section, wherein the cross-sectional plane is oriented perpendicularly to the main extension plane 11 of the micromechanical device 100. The gas phase etching has created access approximately in a Z-shape to the blind hole 24 from the space above a sensor core layer 70 via the volume previously occupied by a substructure 60. The residues of the lithography mask 71 that remain after the trench etching have been removed by the gas phase etching, except for the portion protected by the standoff layer 72.

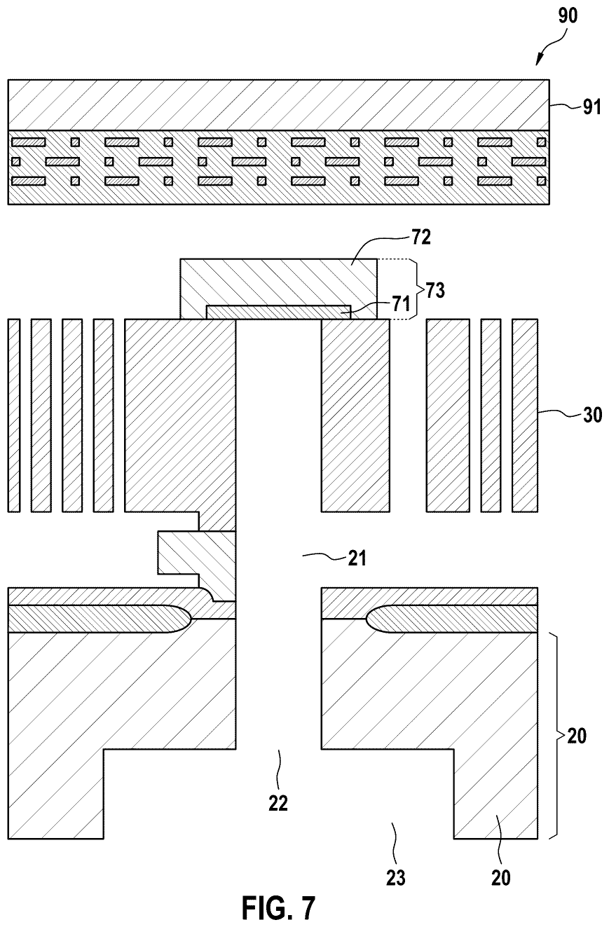

In FIG. 7, a fully processed cavern access 21 and a surrounding region of a micromechanical device 100 according to the present invention in the state after the trench etching from the rear side of the MEMS substrate 20 and after eutectic bonding of the MEMS substrate 20 to the cap part 90 are shown in cross-section (but regions of the MEMS substrate 20 and of the cap part 90 that are bonded together are not shown in FIG. 7), wherein the cross-sectional plane is oriented perpendicularly to the main extension plane 11 of the micromechanical device 100. The trench etching from the rear side of the MEMS substrate 20 has created access in a Z-shape to the external environment of the micromechanical device 100 from the cavern 40 surrounding the sensor core and formed after the bonding (cf. FIG. 1). The portions of an ASIC circuit located above the standoff layer 72 and above the buried portion of the lithograph mask 71 are protected both from the trench etching, by which the blind hole 24 is pierced, and from the laser radiation, which is used after tempering and setting the target internal pressure to melt and seal a cavern access opening 22.

What is claimed is:

1. A micromechanical device, comprising:
a micromechanical system including a MEMS substrate and a functional layer; and
a cap part connected to the micromechanical system, wherein the functional layer is located between the MEMS substrate and the cap part, wherein the cap part includes a cap substrate, wherein the micromechanical device has a main extension plane, wherein the micromechanical system and the cap part enclose a cavern, wherein the micromechanical device has a sealed cavern access and the cavern access is formed through at least a portion of the MEMS substrate, and straight lines that run perpendicularly to the main extension plane and through the portion of the cavern access that is formed in the MEMS substrate intersect a solid protective material that absorbs and/or reflects and/or scatters laser radiation, wherein the protective material is located in a space between a side of the cap part that faces the MEMS substrate and a side of a seal of the cavern access that faces the cap part.

2. The micromechanical device according to claim 1, wherein the protective material is resistant to etching methods used for etching semiconductor layers, wherein the protective material is located in the space between the side of the cap part that faces the MEMS substrate and the side of the seal of the cavern access that faces the cap part.

3. The micromechanical device according to claim 1, wherein, in addition to being configured to extend through at least a portion of the MEMS substrate perpendicularly to the main extension plane, the cavern access is formed through at least a portion of the micromechanical device in a direction substantially parallel to the main extension plane.

4. The micromechanical device according to claim 1, wherein the cavern access is sealed with a firmly bonded seal, wherein the firmly bonded seal is arranged on a surface of the MEMS substrate, and includes a solidified melt of the material of the MEMS substrate and is a laser fusion seal, wherein the MEMS substrate includes a recess having a bottom, wherein the seal of the cavern access is arranged on the bottom to the recess.

5. A method for producing a micromechanical device including a micromechanical system having a MEMS substrate and a functional layer, and including a cap part connected to the micromechanical system, wherein the functional layer is located between the MEMS substrate and the cap part, wherein the cap part includes a cap substrate, wherein the micromechanical device has a main extension plane, wherein the micromechanical system and the cap part enclose a cavern, wherein the micromechanical device has a cavern access and the cavern access is formed through at least a portion of the MEMS substrate, and each straight line that runs perpendicularly to the main extension plane and through the portion of the cavern access that is formed in the MEMS substrate intersects a solid protective material, wherein the protective material is located in a space between a side of the cap part that faces the MEMS substrate and a side of a seal of the cavern access that faces the cap part, wherein the method for implementing the sealed cavern access comprises the following steps:
in a first step, producing a substructure of the functional layer on a first side of the MEMS substrate that later faces the cap substrate including an ASIC substrate, wherein the substructure includes oxides and semiconductor oxides and has, in at least one region, a partial structure containing at least one cavity, and the substructure has a recess in a region having the partial structure;
in a second step, producing a blind hole as part of the cavern access on the first side of the MEMS substrate in the region of the recess, wherein the blind hole is produced to be adjacent to the substructure by trench etching;
in a third step, producing a material layer including a polycrystalline silicon layer, on the first side of the MEMS substrate, the blind hole being sealed in the process of the producing, and planarizing the material layer by chemical mechanical planarization by removing a sublayer;
in a fourth step, producing a material layer or material layer stack on the material layer and in a region resulting as an extension of the region of the blind hole perpendicular to the main extension plane in a direction of the later connected cap part;
in a fifth step, producing at least one trench offset from the blind hole in a direction parallel to the main extension plane, the trench penetrating not only all material layers produced on the material layer but also the material layer and extends to or into the partial structure;
in a sixth step, removing the substructure, by an etching method, and a passage between the space on the side of the micromechanical system that later faces the cap part and the blind hole is created;
in a seventh step, connecting the micromechanical system to the cap part by a eutectic bonding process;
in an eighth step, producing the cavern access from a second side of the MEMS substrate that faces away from the cap part, by producing a passage from the second side of the MEMS substrate to the blind hole, by grinding the MEMS substrate and/or by trench etching; and
in a ninth step, sealing the cavern access using a firmly bonded seal using a laser fusion seal.

6. The method according to claim 5, wherein the second step includes a first sub-step, during which a material layer is produced on the substructure and the recess and is doped before the blind hole is produced as part of the cavern access on the first side of the MEMS substrate in the region of the recess, wherein the blind hole is produced to be adjacent to the substructure by trench etching.

7. The method according to claim 5, wherein the material layer or at least one of the material layers of the material layer stack forms the protective material that absorbs and/or reflects and/or scatters laser radiation.

8. The method according to claim 5, wherein the material layer or at least one of the material layers of the material layer stack contains a material that is resistant to etching methods used for etching semiconductor layers.

9. The method according to claim 8, wherein the material layer or at least one of the material layers of the material layer stack, that includes a material that is resistant to etching methods, is protected by a material enclosing it, including a spacer between the cap part and the micromechanical system, from gas phase etching processes, wherein the spacer is protected from etching methods by an oxide mask.

10. The method according to claim 5, wherein the ninth step includes a first sub-step, during which tempering and/or setting of the internal pressure of the cavern is carried out before the cavern access is sealed by a laser fusion seal.
